(19) United States
(12) Patent Application Publication
(10) Pub. No.: US 2025/0343214 A1
(43) Pub. Date: Nov. 6, 2025

(54) HYBRID SILICON PHOTONICS-ON-GLASS SUBSTRATE

(71) Applicant: Cisco Technology, Inc., San Jose, CA (US)

(72) Inventors: Hiren D. THACKER, San Diego, CA (US); Ravi S. TUMMIDI, Breinigsville, PA (US); Norbert SCHLEPPLE, Macungie, PA (US)

(21) Appl. No.: 18/653,498

(22) Filed: May 2, 2024

(51) Int. Cl. H01L 25/16; H01L 21/02; H01L 23/00; H01L 23/498

(52) U.S. Cl. CPC H01L 25/167; H01L 21/02422; H01L 23/49827; H01L 24/08; H01L 24/94; H01L 24/16; H01L 2224/08225; H01L 2224/16245; H01L 2224/94

(57) ABSTRACT

A device having a hybrid silicon photonic-on-glass substrate is provided. The device includes a glass substrate having a plurality of through-glass vias (TGVs), an oxide layer, and metal contacts coupled with the TGVs. The device also includes a silicon photonic layer having metal pads and an oxide layer. The metal pads are bonded with the metal contacts and the oxide layer of the silicon photonic layer is bonded with the oxide layer of the glass substrate such that the silicon photonic layer is hybrid bonded to the glass substrate by a metal-to-metal, oxide-to-oxide hybrid bond. Methods of assembly are also provided.

### TECHNICAL FIELD

Embodiments presented in this disclosure generally relate to a device equipped with a hybrid silicon photonics-on-glass substrate. Embodiments presented in this disclosure also relate to assembly of such devices.

### BACKGROUND

Scaling silicon photonic packages to support faster data transmission rates has proven challenging. Achieving tighter electronic-photonic integration for enhanced signal integrity and power delivery while maintaining the mechanical and/or structural viability of such packages has proven particularly challenging.

### BRIEF DESCRIPTION OF THE DRAWINGS

So that the manner in which the above-recited features of the present disclosure can be understood in detail, a more particular description of the disclosure, briefly summarized above, may be had by reference to embodiments, some of which are illustrated in the appended drawings. It is to be noted, however, that the appended drawings illustrate typical embodiments and are therefore not to be considered limiting; other equally effective embodiments are contemplated.

FIG. 1A is a schematic side view of a device according to one example embodiment of the present disclosure.

FIG. 1B is a close-up view of the device of FIG. 1A according to one example embodiment of the present disclosure.

FIG. 2A is a flow diagram for a method of assembling a device according to one example embodiment of the present disclosure.

FIG. 2B shows a device being assembled according to the method set forth in FIG. 2A.

FIG. 2C is a close-up view of the device of FIG. 2B prior to removal of a silicon handle of a photonic integrated circuit wafer of the device.

FIG. 2D is a close-up view of the device of FIG. 2B after removal of the silicon handle of the photonic integrated circuit wafer of the device.

FIG. 3 is a schematic side view of a device according to another example embodiment of the present disclosure.

FIG. 4A is a flow diagram for a method of assembling a device according to another example embodiment of the present disclosure.

FIG. 4B shows a device being assembled according to the method set forth in FIG. 4A.

FIG. 5A is a schematic side view of a device according to another example embodiment of the present disclosure.

FIG. 5B is a schematic top view of one example device arranged as a co-packaged optical system enabled by a hybrid silicon photonic-on-glass substrate.

FIG. 5C is a schematic top view of one example device arranged as an optically-interconnected computational system enabled by a hybrid silicon photonic-on-glass substrate.

FIG. 6 is a schematic side view of a device having multilayer optical features according to a further example embodiment of the present disclosure.

FIG. 7 is a schematic side view of a device according to a further example embodiment of the present disclosure, with a multiplexing device embedded within a glass substrate of the device.

To facilitate understanding, identical reference numerals have been used, where possible, to designate identical elements that are common to the figures. It is contemplated that elements disclosed in one embodiment may be beneficially used in other embodiments without specific recitation.

### DESCRIPTION OF EXAMPLE EMBODIMENTS

### Overview

One embodiment presented in this disclosure is a device. The device includes a glass substrate having a plurality of through-glass vias (TGVs), an oxide layer, and metal contacts coupled with the TGVs. The device also includes a silicon photonic layer having metal pads and an oxide layer. The metal pads are bonded with the metal contacts and the oxide layer of the silicon photonic layer is bonded with the oxide layer of the glass substrate such that the silicon photonic layer is hybrid bonded to the glass substrate by a metal-to-metal, oxide-to-oxide hybrid bond.

Another embodiment presented in this disclosure is a device. The device includes a glass substrate having a plurality of through-glass vias (TGVs), a plurality of metal contacts coupled with the TGVs, and an oxide layer. The device also includes a silicon photonic layer having a substrate-interface surface and a stackable-interface surface defining a thickness of the silicon photonic layer. The silicon photonic layer has a plurality of metal pads and an oxide layer arranged along the substrate-interface surface and a plurality of stackable metal vias arranged at the stackable-interface surface. The plurality of metal pads are bonded with respective ones of the plurality of metal contacts and the oxide layer of the glass substrate is bonded with the oxide layer of the silicon photonic layer to form a hybrid bond between the glass substrate and the silicon photonic layer. The device also includes an electronic integrated circuit (EIC) stacked on the silicon photonic layer and coupled with the stackable metal vias.

A further embodiment presented in this disclosure is a method. The method includes hybrid bonding a PIC wafer to a glass substrate wafer having through-glass vias (TGVs), the PIC wafer having a wafer-level silicon photonic layer and a wafer-level silicon handle. The method further includes removing the wafer-level silicon handle of the PIC wafer while the wafer-level silicon photonic layer remains hybrid bonded to the glass substrate wafer. The method also includes attaching a plurality of integrated circuits to the wafer-level silicon photonic layer. Further, the method includes performing wafer singulation to create respective electro-optical packages, with each electro-optical package including a silicon photonic layer separated from the wafer-level silicon photonic layer, at least one of the plurality of integrated circuits, and a glass substrate separated from the glass substrate wafer, the glass substrate having at least one of the TGVs. In performing the singulation, at least one electro-optical package of the plurality of electro-optical packages is diced so that an optical interface of the silicon photonic layer is created by the dicing.

### Example Embodiments

Embodiments herein disclose various devices equipped with a hybrid silicon photonics-on-glass substrate, as well as methods of assembling such devices.

In one example aspect, a device can include a glass substrate having top and bottom redistribution layers connected by a plurality of through-glass vias (TGVs). The glass substrate can also include a plurality of metal contacts and an oxide layer arranged at a photonic-interface surface of the glass substrate. The device can also include a silicon photonic layer having a substrate-interface surface and a stackable-interface surface defining a thickness of the silicon photonic layer. The silicon photonic layer also has a plurality of metal pads and an oxide layer arranged at the substrate-interface surface and a plurality of stackable metal vias arranged at the stackable-interface surface. The substrate-interface surface of the silicon photonic layer can be arranged in a face-to-face contact arrangement with the photonic-interface surface of the glass substrate. The metal pads of the silicon photonic layer can be bonded with respective ones of the metal contacts of the glass substrate and the oxide layer of the glass substrate can be bonded with the oxide layer of the silicon photonic layer to form a hybrid bond between the glass substrate and the silicon photonic layer, e.g., a metal-to-metal, oxide-to-oxide hybrid bond, or in some aspects, a copper-to-copper, oxide-to-oxide hybrid bond. One or more Integrated Circuits (ICs) can be stacked on the silicon photonic layer, such as an Electronic Integrated Circuit (EIC), an Application-Specific Integrated Circuit (ASIC), a memory device, some combination thereof, etc. The stacked one or more ICs can be coupled with the stackable metal vias of the silicon photonic layer.

In some aspects, assembly of such devices can be performed at a wafer level with wafer singulation being utilized to create individual devices. In at least some example implementations, a PIC wafer can be hybrid bonded to a glass substrate wafer having TGVs. The PIC wafer can be hybrid bonded to the glass substrate wafer by way of a metal-to-metal, oxide-to-oxide hybrid bond, for example. The PIC wafer can have a wafer-level silicon photonic layer and a wafer-level silicon handle. During hybrid bonding, the PIC wafer can be inverted (or flipped) so that the wafer-level silicon photonic layer is arranged face-to-face with the glass substrate wafer and hybrid bonded thereto. Once the PIC wafer, or specifically the wafer-level silicon photonic layer, is hybrid bonded to the glass substrate wafer, the wafer-level silicon handle of the PIC wafer is removed while the wafer-level silicon photonic layer remains hybrid bonded to the glass substrate wafer. This effectively reduces the thickness of the package and eliminates the substrate upon which the wafer-level silicon photonic layer is built up during fabrication. Further, removing the wafer-level silicon handle reveals the stackable metal vias at the stackable-interface surface of the wafer-level silicon photonic layer. The stackable metal vias can provide electrical coupling points for components stacked on the wafer-level silicon photonic layer. In some aspects, a plurality of components, such as EICs, ASICs, light sources, a combination thereof, etc., can be attached to the wafer-level silicon photonic layer, e.g., by hybrid bonding or by other techniques. Next, wafer singulation can be performed to create respective electro-optical packages, with each electro-optical package including a silicon photonic layer separated from the wafer-level silicon photonic layer, a glass substrate having TGVs separated from the glass substrate wafer, and one or more components stacked on the silicon photonic layer. In performing the singulation, at least one electro-optical package can be diced so that an optical interface of the silicon photonic layer of that electro-optical package is created by the dicing. One or more optical fibers, e.g., support by respective Fiber Array Units (FAUs), can be coupled with the electro-optical packages at their respective optical interfaces.

The device and assembly methods disclosed herein can provide one or more advantages, benefits, and/or technical effects. For instance, the devices disclosed herein can provide improved electrical performance, such as signal integrity and power integrity, which may be particularly useful for supporting high speed data rates (e.g., 112 G/224 G signaling). Hybrid bonding can provide ultra-small bump size and dense integration between the silicon photonic layer and the glass substrate and between the silicon photonic layer and components stacked thereon. In addition, hybrid bonding can provide fewer physical transitions in the signal path, and can eliminate organic substrates and Through-Silicon Vias (TSVs) extending through a silicon handle, which can reduce the processing complexity of the device. Further, high density electrical routing on or in the silicon photonic layer, and in some instances the top side of the glass substrate, can allow for shorter electrical paths, compact designs, and lower power. Such electrical routing can be provided to couple ICs stacked on the silicon photonic layer together. Furthermore, the Coefficients of Thermal Expansion-matched (or CTE-matched) glass substrate can provide enhanced support of photonic packaging, such as edge coupling warpage control. This enhanced CTE-matching can enable opportunities for edge and surface coupling of FAUs. Also, an edge coupling optical interface can be formed at the same time as singulation of the device from the wafer-to-wafer assembly.

In addition, the glass substrate can enable optical interconnection, such as optical routing and fanout in the glass substrate. Further, the use of a glass substrate enables offloading of passive optical elements (e.g., optical waveguides, wavelength and/or polarization Multiplexers/Demultiplexers (MUX/DEMUX), mode size converters, some combination thereof, etc.) to the glass substrate, which can reduce the footprint of the silicon photonic layer and components stacked on the silicon photonic layer. The devices disclosed herein can also be assembled by leveraging the advantages associated with wafer level assembly, enabling wafer-level testing to determine known good electrical-optical packages or known good dies for further assembly. Light sources can also be integrated at the wafer-level, e.g., to construct one or more devices as optical engines. In addition, the device is scalable and can enable low-latency optically interconnected multi-chip systems. The device and methods of fabrication can have other advantages, benefits, and/or technical effects besides those noted herein.

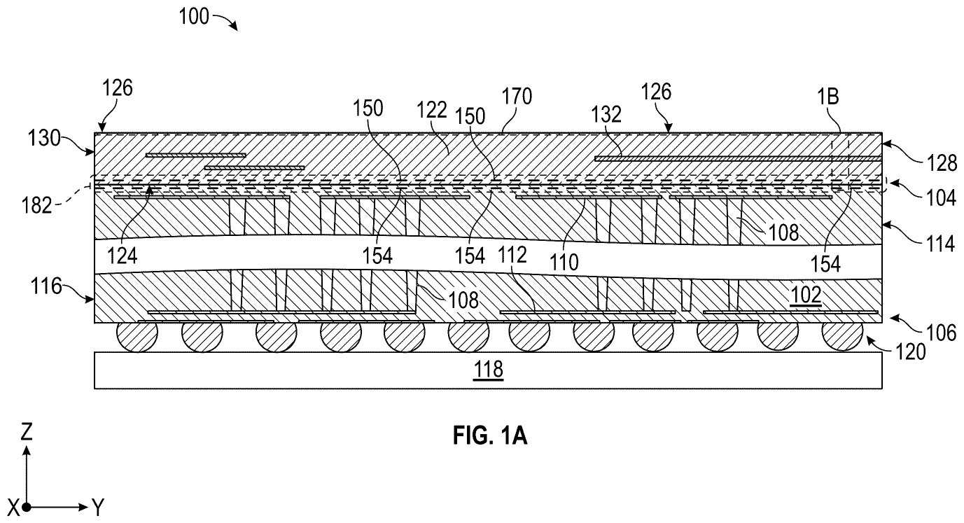

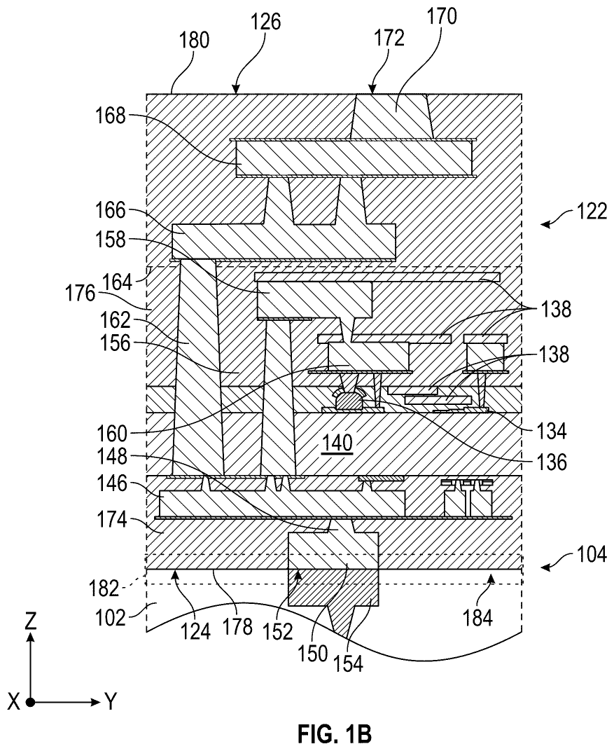

Referring now to the drawings, FIG. 1A is a schematic side view of a device 100, according to one example embodiment of the present disclosure. For the depicted embodiment of FIG. 1A, the device 100 is a hybrid silicon photonic-on-glass substrate platform. For reference, the device 100 defines a first direction X, a second direction Y, and a third direction Z, which are mutually perpendicular to one another and form an orthogonal direction system. The first direction X can be a transverse direction, the second direction Y can be a lateral direction, and the third direction Z can be a vertical direction, for example.

The device 100 includes a glass substrate 102 having a top side 104 and a bottom side 106 that define a thickness of the glass substrate 102 along the third direction Z. The glass substrate 102 has metallization (e.g., copper metallization) for high and low speed signal transmission and power delivery. Particularly, the glass substrate 102 has a plurality of TGVs 108 that carry signals, power, and/or ground, e.g., between a top redistribution layer 110 and a bottom redistribution layer 112, with each one of the redistribution layers 110, 112 including one or more layers. Multiple layers of redistribution at the top and bottom of the glass substrate 102 can provide signal fallout. TGVs can also be referred to as Through-Dielectric Vias, or TDVs. The TGVs 108 can be formed of copper, for example. The glass substrate 102 also has a first side edge 114 and a second side edge 116 that define a length of the glass substrate 102 along the second direction Y. The bottom side 106 of the glass substrate 102 can be coupled with, e.g., a Printed Circuit Board (PCB), or PCB 118, by way of Ball Grid Arrays (BGA), or BGAs 120. In some embodiments, the glass substrate 102 can be about one hundred (100) microns to about one (1) millimeter thick. As used herein, “about” or other terms of approximation means within five percent (5%) of a stated value.

The device 100 also includes a silicon photonic layer 122 stacked on the glass substrate 102. The silicon photonic layer 122 has a substrate-interface surface 124 and a stackable-interface surface 126 that define a thickness of the silicon photonic layer 122 along the third direction Z. The thickness of the silicon photonic layer 122 can be twenty (20) microns or less, for example. In some embodiments, a thickness ratio defined as a thickness of the glass substrate 102 to a thickness of the silicon photonic layer 122 is between 5:1 and 40:1, including the endpoints of the range. As one example, the glass substrate 102 can have a thickness of 100 microns and the silicon photonic layer 122 can have a thickness of 20 microns, which equates to a 5:1 thickness ratio. As another example, the glass substrate 102 can have a thickness of 800 microns and the silicon photonic layer 122 can have a thickness of 20 microns, which equates to a 40:1 thickness ratio. In at least some example embodiments, the silicon photonic layer 122 does not include a silicon handle or silicon substrate upon which the silicon photonic layer 122 is built up during fabrication. As will be explained herein, such a silicon handle can be removed from the silicon photonic layer 122. In this regard, the photonic layer of the device 100 can be absent a silicon handle or silicon substrate, which can reduce the overall thickness of the device 100.

The silicon photonic layer 122 also has a first side edge 128 and a second side edge 130 that define a length of the silicon photonic layer 122 along the second direction Y. The first side edge 128 can provide an optical interface or optical facet of the silicon photonic layer 122. As illustrated in FIG. 1A, the silicon photonic layer 122 includes a prong coupler 132, which can optically couple one or more fibers, such as fibers carried by a Fiber Array Unit (FAU), with the optical components of the silicon photonic layer 122. In some embodiments, the glass substrate 102 can include mechanical features for FAU location and attachment, such as an etched pocket upon which the FAU can be seated and/or U- or V-grooves to align the optical fibers with the prong coupler 132. The prong coupler 132 is arranged at the first side edge 128 and extends along the second direction Y toward the second side edge 130. In some assembly implementations, the silicon photonic layer 122 and the glass substrate 102 can be diced, with the silicon photonic layer 122 arranged on the glass substrate 102, so that the first side edge 128 of the silicon photonic layer 122 and the first side edge 114 of the glass substrate 102 are formed concurrently or in a single dice movement (e.g., in a single laser pass), rendering diced coplanar edges.

FIG. 1B is a close-up view of the device 100 of FIG. 1A, taken from Section 1B in FIG. 1A. More specifically, FIG. 1B shows a close-up view of the silicon photonic layer 122 and a portion of the glass substrate 102. As illustrated in FIG. 1B, the silicon photonic layer 122 has, among other things, an optical modulator 134 (e.g., an integrated high speed Semiconductor-Insulator-Semi-conductor Capacitor modulator or SISCAP modulator), an optical detector 136 (e.g., a Germanium Photo Diode or GePD), silicon nitride waveguides 138, a buried insulation layer 140 (also referred to as a buried oxide (BOX) layer), and a conductive pathway formed by interconnected metal layers and metal vias (e.g., copper layers and copper vias). Some or all of the components of the conductive pathway can be formed by copper, for example.

The conductive pathway of the silicon photonic layer 122 can include a hub layer 146 arranged on a side of the buried insulation layer 140 facing the substrate-interface surface 124. A metal via 148 connects the hub layer 146 with a metal pad 150. The metal pad 150 is arranged flush with the substrate-interface surface 124, which is arranged in contact with the glass substrate 102. That is, a contact surface 152 of the metal pad 150 is arranged flush with the substrate-interface surface 124. The metal pad 150 can be bonded to a metal contact 154 arranged at a photonic-interface surface of the glass substrate 102. Such an arrangement can facilitate hybrid bonding (e.g., a metal-to-metal, oxide-to-oxide hybrid bond) between the silicon photonic layer 122 and the glass substrate 102, as will be explained further below. The bonding of the metal pad 150 to the metal contact 154 can electrically couple the silicon photonic layer 122 with the glass substrate 102. Although only one metal pad 150 is shown in the close-up view in FIG. 1B, it will be appreciated that the silicon photonic layer 122 can include a plurality of metal pads arranged along the substrate-interface surface 124, e.g., as shown in FIG. 1A.

The hub layer 146 is also coupled with other components of the silicon photonic layer 122. Further, metal vias can connect the hub layer 146 with a first through-buried oxide via 156 that traverses through the buried insulation layer 140. The first through-buried oxide via 156 connects to an intermediary layer 158, which in turn is connected to a detector-interface layer 160 by way of a metal via. The detector-interface layer 160 can be coupled with the optical detector 136. In addition, a metal via connects the hub layer 146 with a second through-buried oxide via 162 that traverses through the buried insulation layer 140 and across a wafer bond interface 164 to a first intermediary layer 166. Vias can connect the first intermediary layer 166 with a second intermediary layer 168. The second through-buried oxide via 162, the first intermediary layer 166, and the second intermediary layer 168 can each be formed of copper. A stackable metal via 170 is connected to the second intermediary layer 168. A contact surface 172 of the stackable metal via 170 can be arranged flush with the stackable-interface surface 126. In this way, the stackable metal via 170 can be bonded to a metal contact of a chip or device stacked on the silicon photonic layer 122. Such an arrangement can facilitate hybrid bonding (e.g., a metal-to-metal, oxide-to-oxide hybrid bond) between the silicon photonic layer 122 and the chip or device stacked thereon, as will be explained further below.

In some alternative embodiments, the silicon photonic layer 122 can be “cut off” at the wafer bond interface 164 and the second through-buried oxide via 162 can provide a contact surface to which a metal contact of a chip or device stacked thereon can contact for hybrid bonding purposes. The stackable-interface surface 126 can be arranged where the wafer bond interface 164 is shown in FIG. 1B and the contact surface of the second through-oxide via 162 can be flush with this “moved” stackable-interface surface. In this manner, in such alternative embodiments, the second through-oxide via 162 can extend through the buried insulation layer 140 and to the stackable-interface surface.

The elements of the silicon photonic layer 122 can be arranged in one or more oxide layers. The oxide layers can be formed of silicon oxide, for example. The oxide layers can include a substrate-interface oxide layer 174 and one or more stackable-interface oxide layers 176. In at least some example embodiments, a dielectric layer 178, e.g., a thin film formed of silicon carbon nitride (SiCN), can be arranged at the substrate-interface surface 124, which may enhance hybrid bonding between the silicon photonic layer 122 and the glass substrate 102. Further, in at least some example embodiments, a stackable dielectric layer 180, e.g., a thin film formed of silicon carbon nitride (SiCN), can be arranged at the stackable-interface surface 126, which may enhance hybrid bonding between the silicon photonic layer 122 and a chip or device stacked thereon.

The silicon photonic layer 122 can be bonded to the glass substrate 102 by way of a hybrid bond 182, such as a metal-to-metal, oxide-to-oxide hybrid bond, or in at least some example embodiments, a copper-to-copper, oxide-to-oxide hybrid bond. At the substrate-interface surface 124 of the silicon photonic layer 122, the silicon photonic layer 122 can include the substrate-interface oxide layer 174 (and in some embodiments, the dielectric layer 178) and a plurality of metal pads spaced apart from one another, with the metal pad 150 of FIG. 1B being one of the plurality of metal pads. FIG. 1A shows a plurality of metal pads 150 at the substrate-interface surface 124. Similarly, at the top side 104 of the glass substrate 102, the glass substrate 102 can include an oxide layer 184 and a plurality of metal contacts 154 spaced apart from one another. FIG. 1A shows a plurality of metal contacts 154 arranged at the photonic-interface surface or top side 104 of the glass substrate 102. During hybrid bonding, a metal-to-metal bond (e.g., a copper-to-copper bond) can be formed between the metal contacts 154 of the glass substrate 102 and the metal contacts (e.g., the metal pads 150) of the silicon photonic layer 122, and an oxide-to-oxide bond can be formed between the oxide layer 184 of the glass substrate 102 and the substrate-interface oxide layer 174 of the silicon photonic layer 122. FIG. 1B shows a close-up of one of the metal pads 150 in bonded engagement with one of the metal contacts 154 and the substrate-interface oxide layer 174 in bonded engagement with the oxide layer 184, on both sides of the metal-to-metal bond. Such a hybrid bond can provide coupling between the silicon photonic layer 122 and the glass substrate 102 and also enables the glass substrate 102 to mechanically support the silicon photonic layer 122, which can be constructed relatively thin (e.g., less than or equal to 20 microns). Further, such a hybrid bond can enable tight tolerance and flatness control for enhancing optical input/output of the device 100.

In some embodiments, an entirety of the substrate-interface surface 124 is supported and hybrid bonded to the glass substrate 102 by the hybrid bond 182. That is, one hundred percent (100%) of the area of the silicon photonic layer 122 (or an entirety of the substrate-interface surface 124) can be hybrid bonded to, and in intimate contact with, the glass substrate 102 by the hybrid bond 182. In other embodiments, at least ninety-five percent (95%) of the area of the silicon photonic layer 122 can be hybrid bonded to, and in intimate contact with, the glass substrate 102 by the hybrid bond 182. Such embodiments can ensure that the silicon photonic layer 122 is mechanically supported by the glass substrate 102 in a satisfactory manner. The hybrid bond 182 and arrangement of the components can allow for planar-to-planar or face-to-face bonding of the glass substrate 102 and the silicon photonic layer 122, which can reduce the overall packaging of the device 100.

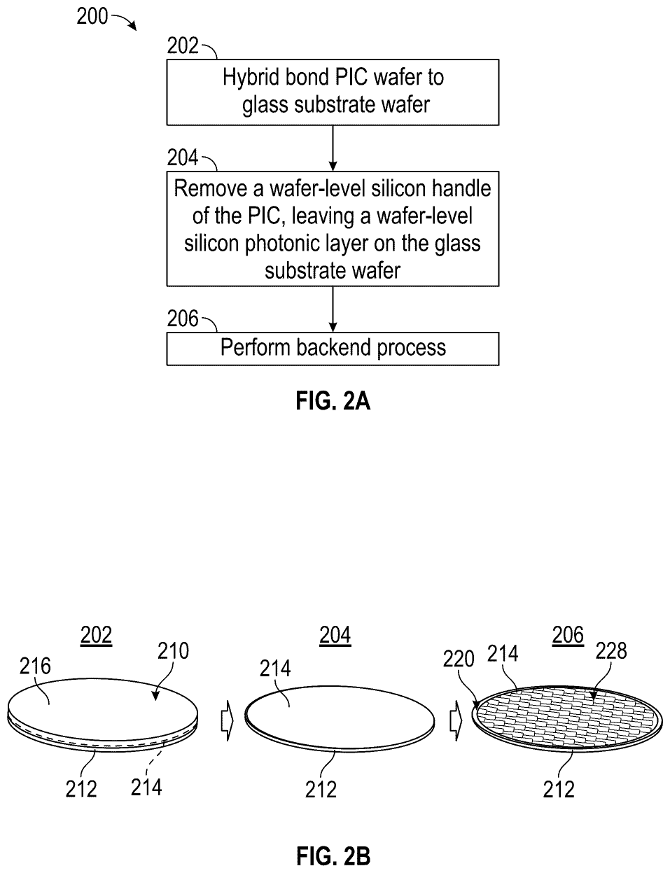

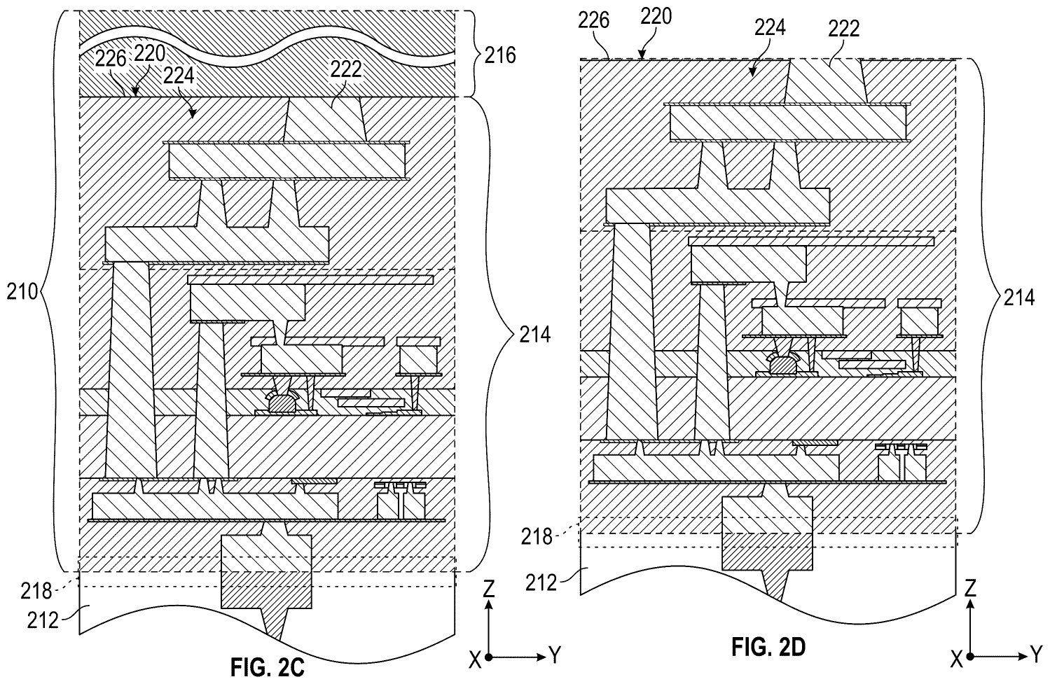

With reference now to FIGS. 2A and 2B, FIG. 2A is a flow diagram for a method 200 of assembling a device (or many devices) according to one example embodiment of the present disclosure. For instance, the method 200 can be used to assemble the device 100 of FIG. 1A, for example. FIG. 2B shows a device being assembled according to the method 200 set forth in FIG. 2A.

At 202, the method 200 can include hybrid bonding a PIC wafer to a glass substrate wafer. The PIC wafer can have a silicon photonic layer and a silicon handle, and the glass substrate wafer can have TGVs. For instance, as shown in FIG. 2B at 202, a PIC wafer 210 is shown hybrid bonded to a glass substrate wafer 212, e.g., by way of a metal-to-metal, oxide-to-oxide hybrid bond.

More specifically, as illustrated in FIG. 2B at 202, the PIC wafer 210 has a wafer-level silicon photonic layer 214 and a wafer-level silicon handle 216. To arrange the PIC wafer 210 with the glass substrate wafer 212 for hybrid bonding, the PIC wafer 210 can be inverted (or flipped) so that the wafer-level silicon photonic layer 214 is arranged in a face-to-face manner with a top surface of the glass substrate wafer 212. Accordingly, the wafer-level silicon handle 216 upon which the wafer-level silicon photonic layer 214 is fabricated does not contact the top surface of the glass substrate wafer 212, or stated differently, the wafer-level silicon handle 216 is spaced from the glass substrate wafer 212 by the thickness of the wafer-level silicon photonic layer 214. The glass substrate wafer 212 has TGVs, redistribution layers, and metal contacts arranged to match with respective metal pads of the wafer-level silicon photonic layer 214. For example, the TGVs, redistribution layers, and metal contacts of the glass substrate wafer 212 can be arranged in a same or similar manner as in the glass substrate 102 of FIG. 1A. With the wafer-level silicon photonic layer 214 arranged in a face-to-face manner with the top surface of the glass substrate wafer 212, the wafer-level silicon photonic layer 214 can be hybrid bonded to the glass substrate wafer 212, e.g., by way of a metal-to-metal, oxide-to-oxide hybrid bond. In some implementations, the glass substrate wafer 212 can be fully fabricated with TGVs, redistribution layers, and metal contacts and the wafer-level silicon photonic layer 214 can be fully fabricated (e.g., with the elements described above with respect to the silicon photonic layer 122 of FIG. 1A) prior to the hybrid bonding at 202.

In some implementations, particularly when optical engines are to be formed from the bonded PIC wafer 210 and the glass substrate wafer 212 (e.g., by dicing the assembly during a singulation process), the glass substrate wafer 212 can include a plurality of metallization sets, with each metallization set including TGVs, redistribution layers, and metal contacts organized in a manner to correspond to predefined mounting locations of the components to be stacked directly or indirectly thereon. Such components can include, without limitation, Electronic Integrated Circuits (EICs), ASICs, light sources, etc. The strategic arrangement of the metallization sets (rather than having TGVs, redistribution layers, and metal contacts arranged across the entire glass substrate wafer 212) can reduce material and labor costs and can reduce processing time. In some implementations, the metallization sets can be arranged as repeating sets that can abut or be spaced from one another.

At 204, the method 200 can include, with the PIC wafer hybrid bonded to the glass substrate wafer, removing the wafer-level silicon handle of the PIC wafer to leave behind only the wafer-level silicon photonic layer on the glass substrate wafer. For instance, as shown in FIG. 2B at 204, the wafer-level silicon handle 216 (see FIG. 2B at 202) has been removed, and consequently, only the wafer-level silicon photonic layer 214 is left behind on the glass substrate wafer 212. The wafer-level silicon handle 216 can be removed using any suitable process, such as by laser dicing. By removing the wafer-level silicon handle 216, the PIC wafer 210 is reduced to only the wafer-level silicon photonic layer 214. In this regard, the thickness of the assembly can be reduced, which will be appreciated by comparing the thickness of PIC wafer 210 in FIG. 2B at 202 with the thickness of the wafer-level silicon photonic layer 214 in FIG. 2B at 204.

Moreover, in removing the wafer-level silicon handle 216 of the PIC wafer 210, a stackable-interface surface of the wafer-level silicon photonic layer 214 can be revealed or exposed. In this regard, stackable metal vias and an oxide layer at the stackable-interface surface can be revealed and used to hybrid bond other components thereto, such as an EIC. For instance, as shown in FIG. 2C, the PIC wafer 210 is shown hybrid bonded to the glass substrate 102. Particularly, the wafer-level silicon photonic layer 214 is hybrid bonded to the glass substrate wafer 212 by way of hybrid bond 218. Further, in FIG. 2C, the wafer-level silicon handle 216 has not yet been removed. In this regard, a stackable-interface surface 220 of the wafer-level silicon photonic layer 214 is covered up by the wafer-level silicon handle 216 in FIG. 2C. Thus, stackable metal vias 222 (only one via shown in FIG. 2C) and a stackable oxide layer 224 (and/or stackable dielectric layer 226 when present) are covered up or not revealed. Accordingly, FIG. 2C represents the PIC wafer 210 prior to performing the removal of the wafer-level silicon handle 216 at 204.

FIG. 2D represents the assembly after performing the removal of the wafer-level silicon handle 216 at 204. As shown, with removal of the wafer-level silicon handle 216 (FIG. 2C), the stackable metal vias 222 (only one via shown in FIG. 2D) and the stackable oxide layer 224 (and/or stackable dielectric layer 226 when present) are revealed. This allows for chips or other devices to be stacked on the wafer-level silicon photonic layer 214 and hybrid bonded thereto, e.g., by way of a metal-to-metal, oxide-to-oxide hybrid bond. The wafer-level silicon photonic layer 214, or remaining portion of the PIC wafer 210 after performing the removal of the wafer-level silicon handle 216 at 204, does not include a silicon handle or silicon substrate, and consequently, does not include Through-Silicon Vias (TSV).

At 206, the method 200 can include performing a backend process on the silicon photonic layer. For instance, lithography, metal/dielectric deposition, etching, etc. can be employed to build up additional redistribution layers, deposit Under Bump Metallization (UBM), etc. as per the requirements of the downstream assembly. As shown in FIG. 2B at 206, metal material 228 can be deposited on the stackable-interface surface 220 of the wafer-level silicon photonic layer 214.

Accordingly, a device, such as the device 100 of FIG. 1A, can be formed according to the method 200.

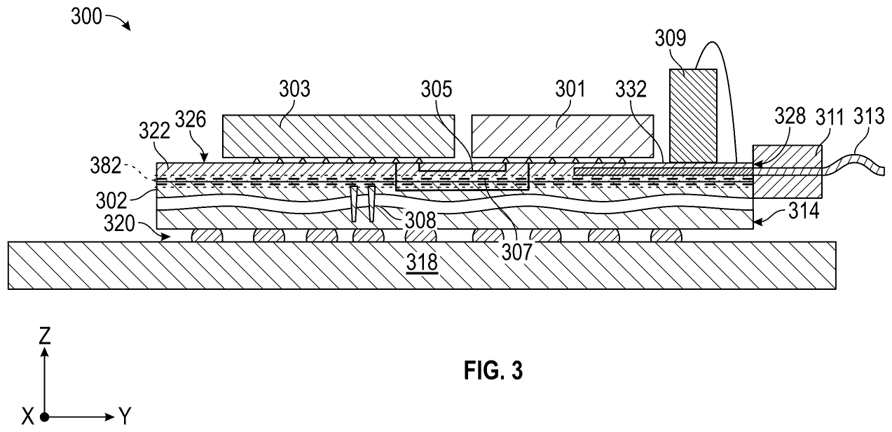

FIG. 3 is a schematic side view of a device 300 according to another example embodiment of the present disclosure. The device 300 of FIG. 3 is constructed in a similar manner as the device 100 of FIG. 1A. Accordingly, similar numerals will be utilized to refer to like structures, except that 300 series numbers will be utilized to describe the device 300 of FIG. 3.

As shown in FIG. 3, the device 300 is arranged as an optical engine, or rather, a hybrid silicon photonic-on-glass substrate optical engine. The device 300 includes a glass substrate 302 arranged on a PCB 318, e.g., by way of BGAs 320. The glass substrate 302 has TGVs 308 spanning along the third direction Z, e.g., between top and bottom RDLs. A silicon photonic layer 322 is stacked on the glass substrate 302 and is bonded thereto by a hybrid bond 382, e.g., by way of a metal-to-metal, oxide-to-oxide hybrid bond.

For this example embodiment, the device 300 includes an Electrical Integrated Circuit (EIC), or EIC 301, that is flipchip bonded to the silicon photonic layer 322. The EIC 301 can include a driver, Rx circuits (e.g., transimpedance amplifier circuits, or TIA circuits), and/or other elements. Stackable metal vias revealed or exposed when a silicon handle is removed from the silicon photonic layer 322 during assembly can provide electrical connection points to which solder bumps can be applied to attach the EIC 301 with a stackable-interface surface 326 of the silicon photonic layer 322. In addition, for the example embodiment of FIG. 3, one or more ASICs 303 (only one shown in FIG. 3), can be stacked on the silicon photonic layer 322 and arranged side-by-side or juxtaposed relative to the EIC 301. The ASIC 303 can be, for example, a Network Processing Unit (NPU), a Graphics Processing Unit (GPU), a Central Processing Unit (CPU), or a Field Programmable Gate Array (FPGA). The ASIC 303 can be flipped and bonded to the silicon photonic layer 322, e.g., by way of solder bumps. In some alternative embodiments, the EIC 301 and/or the ASIC 303 can be hybrid bonded to the silicon photonic layer 322, e.g., by way of a metal-to-metal, oxide-to-oxide hybrid bond. For instance, when the silicon handle is removed during assembly, stackable metal vias and a stackable oxide layer (and/or stackable dielectric layer, when present) can be revealed and used to hybrid bond the EIC 301 and/or ASIC 303 thereto.

The EIC 301 can be electrically coupled with the ASIC 303. For instance, high density local electrical wiring can be used to electrically couple the EIC 301 with the ASIC 303. In FIG. 3, a first electrical wire 305 provides a first electrical path between the EIC 301 and the ASIC 303. The first electrical wire 305 extends into and traverses through the silicon photonic layer 322 to connect respective electrical interconnects, one of which electrically connects the electrical wire 305 with the EIC 301 and one of which electrically connects the electrical wire 305 with the ASIC 303. In addition, a second electrical wire 307 provides a second electrical path between the EIC 301 and the ASIC 303. The second electrical wire 307 connects respective electrical interconnects one which electrically connects the electrical wire 305 with the EIC 301 and one which electrically connects the electrical wire 305 with the ASIC 303. The second electrical wire 307 extends from the interconnect of the EIC 301 through the silicon photonic layer 322 and into the glass substrate 302 along the third direction Z. The second electrical wire 307 then traverses through the upper portion of the glass substrate 302 toward the ASIC 303 along the second direction Y. Next, the second electrical wire 307 extends upward through the silicon photonic layer 322 and connects with the interconnect of the ASIC 303. In other embodiments, more or less than the number of electrical wires shown in FIG. 3 can be provided to electrically couple the EIC 301 and the ASIC 303. Electrical wires can extend through the silicon photonic layer 322 or the glass substrate 302, or both.

A light source 309 can be stacked on the silicon photonic layer 322, or rather, coupled with the stackable-interface surface 326 thereof as illustrated in FIG. 3. The light source 309, e.g., a Laser MicroPackage (LaMP), can be attached to the silicon photonic layer 322 to inject optical power into the device 300. Similarly, an optical gain material (e.g., a Semiconductor Optical Amplifier (SOA)) can be bonded onto the silicon photonic layer 322 and integrated with the waveguide network and photonic devices thereof.

The silicon photonic layer 322 also has a prong coupler 332 that optically couples a Fiber Array Unit, or FAU 311, with waveguides of the silicon photonic layer 322. The FAU 311 can include one or more optical fibers 313 (e.g., single mode optical fibers) optically coupled with the prong coupler 332 as shown in FIG. 3. In at least some embodiments, an index matching epoxy can couple the FAU 311 with the silicon photonic layer 322 and the glass substrate 302. The silicon photonic layer 322 has a first side edge 328, which provides an optical interface or optical facet between the FAU 311 and the silicon photonic layer 322, can be substantially coplanar with the first side edge 314 of the glass substrate 302. That is, the first side edge 328 of the silicon photonic layer 322 can be arranged in a same or substantially a same plane as the first side edge 314 of the glass substrate 302, wherein the plane is orthogonal to the second direction Y. As will be explained further below, the silicon photonic layer 322 and the glass substrate 302 can be diced, with the silicon photonic layer 322 arranged on the glass substrate 302, so that the first side edge 328 of the silicon photonic layer 322 and the first side edge 314 of the glass substrate 302 are formed concurrently or in a single dice movement (e.g., in a single laser pass), rendering diced coplanar edges. While the FAU 311 is shown as an edge coupled FAU in FIG. 3, in alternative embodiments, the FAU 311 can be a surface coupled FAU, or rather attached to the stackable-interface surface 326 of the silicon photonic layer 322.

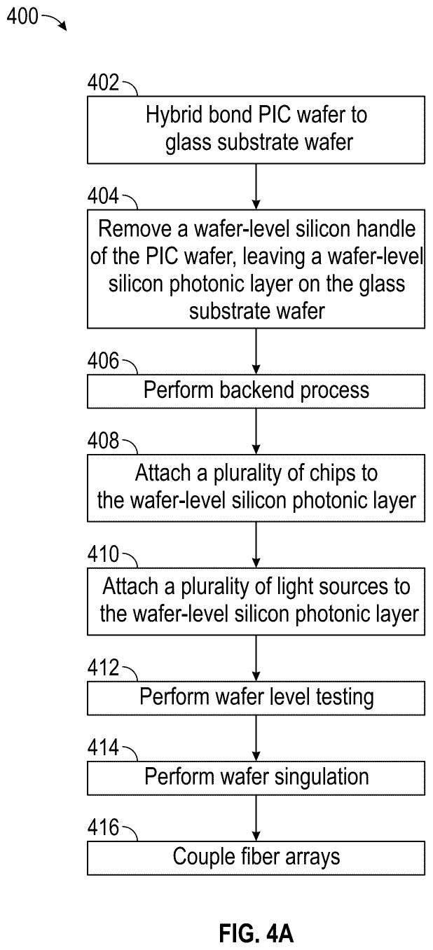

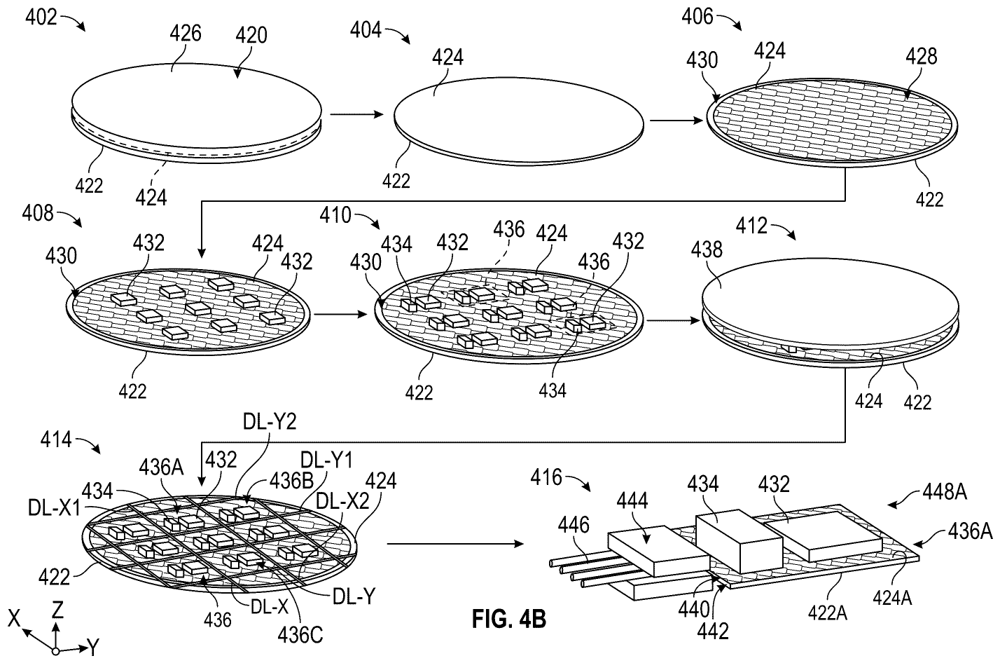

With reference now to FIGS. 4A and 4B, FIG. 4A is a flow diagram for a method 400 of assembling a device (or many devices) according to one example embodiment of the present disclosure. For instance, the method 400 can be used to assemble the device 300 of FIG. 3 arranged as an optical engine. FIG. 4B shows a device being assembled according to the method 400 set forth in FIG. 4A.

At 402, the method 400 can include hybrid bonding a PIC wafer to a glass substrate wafer. The PIC wafer can have a silicon photonic layer and a silicon handle, and the glass substrate wafer can have TGVs. For instance, as shown in FIG. 4B at 402, a PIC wafer 420 is shown hybrid bonded to a glass substrate wafer 422, e.g., by way of a metal-to-metal, oxide-to-oxide hybrid bond. More specifically, as illustrated in FIG. 4B at 402, the PIC wafer 420 has a wafer-level silicon photonic layer 424 and a wafer-level silicon handle 426. To arrange the PIC wafer 420 with the glass substrate wafer 422 for hybrid bonding, the PIC wafer 420 can be inverted (or flipped) so that the wafer-level silicon photonic layer 424 is arranged in a face-to-face manner with a top surface of the glass substrate wafer 422. Accordingly, the wafer-level silicon handle 426 upon which the wafer-level silicon photonic layer 424 is assembled does not contact the top surface of the glass substrate wafer 422. The glass substrate wafer 422 has TGVs, redistribution layers, and metal contacts arranged to match with respective metal pads of the wafer-level silicon photonic layer 424. For example, the TGVs, redistribution layers, and metal contacts of the glass substrate wafer 422 can be arranged in a same or similar manner as in the glass substrate 302 of FIG. 3 (or the glass substrate 102 of FIG. 1A). With the wafer-level silicon photonic layer 424 arranged in a face-to-face manner with the top surface of the glass substrate wafer 422, the wafer-level silicon photonic layer 424 can be hybrid bonded to the glass substrate wafer 422, e.g., by way of a metal-to-metal, oxide-to-oxide hybrid bond. In this way, the PIC wafer 420 is hybrid bonded to the glass substrate wafer 422 in a facedown orientation. That is, the PIC wafer 420 is bonded to the glass substrate wafer 422 in an inverted orientation with respect to the orientation in which the wafer-level silicon photonic layer 424 is built up on the wafer-level silicon handle 426.

In some implementations, the glass substrate wafer 422 can be fully fabricated with TGVs, redistribution layers, and metal contacts and the wafer-level silicon photonic layer 424 can be fully fabricated (e.g., with the elements described above with respect to the silicon photonic layer 322 of FIG. 3 or the silicon photonic layer 122 of FIG. 1A) prior to the hybrid bonding at 402.

At 404, the method 400 can include, with the PIC wafer hybrid bonded to the glass substrate wafer, removing the silicon handle of the PIC wafer to leave behind only the silicon photonic layer on the glass substrate wafer. For instance, as shown in FIG. 4B at 404, the wafer-level silicon handle 426 (see FIG. 4B at 402) has been removed, and consequently, only the wafer-level silicon photonic layer 424 is left behind on the glass substrate wafer 422. The wafer-level silicon handle 426 can be removed using any suitable process, such as by laser dicing. By removing the wafer-level silicon handle 426, the PIC wafer 420 is reduced to only the wafer-level silicon photonic layer 424. In this regard, the thickness of the assembly can be reduced, which will be appreciated by comparing the thickness of PIC wafer 420 in FIG. 4B at 402 with the thickness of the wafer-level silicon photonic layer 424 in FIG. 4B at 404. In removing the wafer-level silicon handle 426 of the PIC wafer 420, a stackable-interface surface of the wafer-level silicon photonic layer 424 can be revealed or exposed (similar to the stackable-interface surface 220 of the wafer-level silicon photonic layer 214 being revealed as shown in FIG. 2D compared to FIG. 2C where the stackable-interface surface 220 is covered by the silicon handle 206). In this regard, stackable metal vias and a stackable oxide layer (and/or stackable dielectric layer 226 when present) at the stackable-interface surface can be revealed and used to bond (e.g., hybrid bond) other components thereto, such as an EIC and/or other ICs.

At 406, the method 400 can include performing a backend process on the silicon photonic layer. For instance, lithography, metal/dielectric deposition, etching, etc. can be employed to build up additional redistribution layers, deposit UBM, etc. as per the requirements of the downstream assembly. As shown in FIG. 4B at 406, metal material 428 can be deposited on the stackable-interface surface 430 of the wafer-level silicon photonic layer 424.

At 408, the method 400 can include attaching a plurality of chips to the silicon photonic layer. For instance, as shown in FIG. 4B at 408, a plurality of EICs 432 are attached to the stackable-interface surface 430 of the wafer-level silicon photonic layer 424. In some implementations, in attaching the EICs 432 to the wafer-level silicon photonic layer 424, the EICs 432 are hybrid bonded to the wafer-level silicon photonic layer 424, e.g., via metal-to-metal, oxide-to-oxide hybrid bonds. In such implementations, the wafer-level silicon photonic layer 424 can have a plurality of stackable metal vias at the stackable-interface surface 430, with each stackable metal via having a contact surface. The stackable metal vias, which can be formed of copper, can be bonded to respective metal contacts of the EICs 432. The wafer-level silicon photonic layer 424 can also include a stackable oxide layer (and/or stackable dielectric layer when present) at the stackable-interface surface 430. The stackable oxide layer can bond with respective oxide layers of the EICs 432. In other implementations, the EICs 432 can be attached to the wafer-level silicon photonic layer 424 using a copper pillar flip chip process, a microbump flip chip technique, or a thermocompression bonding process. In some implementations, some combination of these techniques can be used, including hybrid bonding in combination with one or more of the other noted techniques. The EICs 432 can be arranged on the wafer-level silicon photonic layer 424 in an array, e.g., in rows and columns as shown in FIG. 4B at 408. Further, in some implementations, after EIC-silicon photonic layer bonding at 408, the method 400 can include performing wafer level testing to confirm Chip-on-silicon photonic layer-on-glass substrate assembly has been performed in a satisfactory manner.

At 410, the method 400 can include attaching light sources to the silicon photonic layer. For instance, as shown in FIG. 4B at 410, a plurality of light sources 434 (e.g., laser sources) are attached to the stackable-interface surface 430 of the wafer-level silicon photonic layer 424 at the wafer level. Each one of the light sources 434 is arranged adjacent to one of the EICs 432. The light sources 434 can be attached or coupled with the wafer-level silicon photonic layer 424 using any suitable technique.

At 412, the method 400 can include performing, prior to wafer singulation at 414, a wafer level test using a test card to test which electro-optical packages satisfy an operational threshold. For instance, a plurality of electro-optical packages 436 can be formed, e.g., by implementing 402-410 of the method 400, with each one of the electro-optical packages 436 including one of the plurality of EICs 432, one of the plurality of light sources 434, a portion of the wafer-level silicon photonic layer 424 (e.g., a portion upon which electro-optical elements are mounted), and a portion of the glass substrate wafer 422 (e.g., a portion upon which electro-optical elements and the wafer-level silicon photonic layer 424 are mounted). In FIG. 4B, nine (9) electro-optical packages 436 are formed at 410, and these electro-optical packages 436 are tested at 412. In other implementations, more or less than nine (9) electro-optical packages 436 can be formed. As illustrated in FIG. 4B, a test card 438 can be placed on top of electro-optical packages 436 and the test card 438 can be used to test which ones of the electro-optical packages 436 are “good packages” by satisfying an operational threshold, such as which ones produce a predetermined electric current, a predetermined voltage, a predetermined optical intensity, etc.

At 414, the method 400 can include performing wafer singulation to create respective electro-optical packages, with each electro-optical package including a silicon photonic layer separated from the wafer-level silicon photonic layer, at least one of the plurality of chips, at least one of the plurality of light sources, and a glass substrate separated from the wafer-level glass substrate, with the glass substrate having at least one of the TGVs. In performing the singulation, at least one electro-optical package is diced so that an optical interface of the silicon photonic layer is created by the dicing.

For instance, as shown in FIG. 4B at 414, dicing can be used to singulate the electro-optical packages 436 according to dicing lines. Some of the dicing lines DL-X are arranged along the first direction X while some of the dicing lines DL-Y are arranged along the second direction Y. In this regard, performing the singulation process can separate the electro-optical packages 436 into individual packages. Dicing can be done by a number of suitable techniques, such as by laser dicing or some other mechanical dicing technique.

In some implementations, in performing the singulation, at least one electro-optical package, such as a first electro-optical package 436A, of the plurality of electro-optical packages 436 is diced create a diced edge of the silicon photonic layer 424A (FIG. 4B at 416) that is coplanar with a diced edge of the glass substrate 422A (FIG. 4B at 416), wherein the diced edge of the silicon photonic layer 424A functions as an optical interface (e.g., the face to which an FAU and one or more optical fibers thereof can be optically coupled with the optical elements of the silicon photonic layer 424A). For instance, as depicted in FIG. 4B at 414, a first dicing line DL-X1 extending along the first direction X is aligned so that, when dicing is performed, the silicon photonic layer 424A and the glass substrate 422A of the first electro-optical package 436A are diced concurrently to form coplanar side edges, including a first side edge 440 (FIG. 4B at 416) of the silicon photonic layer 424A and a first side edge 442 (FIG. 4B at 416) of the glass substrate 422A. In FIG. 4B at 416, the concurrently diced and coplanar first side edges 440, 442 are depicted. Further, a second dicing line DL-X2 extending along the first direction X is aligned so that, when dicing is performed, coplanar second side edges of the silicon photonic layer 424A and the glass substrate 422A of the first electro-optical package 436A are created. The coplanar second side edges of the first electro-optical package 436A can also be deemed coplanar and concurrently formed first side edges of a second electro-optical package 436B, which is adjacent to the first electro-optical package 436A. Moreover, first and second dicing lines DL-Y1, DL-Y2 extending along the second direction Y are aligned so that, when dicing is performed, the first electro-optical package 436A is separated from the wafer-level silicon photonic layer 424 and the wafer-level glass substrate 422.

In some implementations, in performing the wafer singulation at 414, at least two electro-optical packages of the plurality of electro-optical packages 436 are diced concurrently so that 1) for a first one of the two electro-optical packages, a diced edge of the silicon photonic layer is coplanar with a diced edge of the glass substrate, wherein the diced edge of the silicon photonic layer of the first one functions as an optical interface for the first one; and 2) for a second one of the two electro-optical packages, a diced edge of the silicon photonic layer is coplanar with a diced edge of the glass substrate, wherein the diced edge of the silicon photonic layer of the second one functions as an optical interface for the second one. For instance, the first dicing line DL-X1 is aligned so that, when dicing is performed, the coplanar first side edges of the first electro-optical package 436A are formed concurrently with the coplanar first side edges of the third electro-optical package 436C (as well as concurrently with the coplanar first side edges of the electro-optical package arranged between the first electro-optical package 436A and the third electro-optical package 436C along the first direction X). It will be appreciated that the other dicing lines arranged along the first direction X can similarly concurrently dice respective coplanar first side edges of the electro-optical packages 436 of the other rows.

At 416, the method 400 can include coupling a fiber array unit having one or more fibers to the optical interface of each singulated electro-optical package. For instance, as shown in FIG. 4B at 416, an FAU 444 having a plurality of fibers 446 is coupled with the first side edge 440 of the silicon photonic layer 424A and the first side edge 442 of the glass substrate 422A of the first electro-optical package 436A. In some implementations, an FAU can be attached to each electro-optical package 436 determined to satisfy the operational threshold at 412. In this way, an FAU can be attached to each “good package” of the electro-optical packages 436. Accordingly, testing the electro-optical packages 436 at the wafer level at 412 can facilitate production efficiency, eliminating the need to test each package one-by-one by attaching FAUs thereto.

Once the electro-optical packages 436 are coupled with their respective FAUs at 416, the electro-optical packages 436 can be deemed optical engines. For instance, with the FAU 444 optically coupled with the optical elements of the first electro-optical packages 436A, the first electro-optical packages 436 can be deemed a first optical engine 448A. The first optical engine 448A can then be coupled with a PCB, e.g., as shown in FIG. 3, and implemented in an application, such as a transceiver of a networking apparatus. Accordingly, the optical engines can be assembled according to the method 400 at the wafer level, which enables batch processing.

In some further implementations, the method 400 can include attaching one or more ICs to the silicon photonic layer. For instance, with reference to FIG. 4B at 410, one or more ASICs can be attached to the stackable-interface surface 430 of the wafer-level silicon photonic layer 424, e.g., adjacent to respective ones of the EICs 432. In this regard, the electro-optical packages 436 can also include ASICs in some aspects. In some implementations, in attaching the ASICs to the wafer-level silicon photonic layer 424, the ASICs are hybrid bonded to the wafer-level silicon photonic layer 424, e.g., via metal-to-metal, oxide-to-oxide hybrid bonds. In such implementations, the wafer-level silicon photonic layer 424 can have a plurality of stackable metal vias at the stackable-interface surface 430, with each stackable metal via having a metal contact surface. The copper stackable metal vias can be bonded to respective metal contacts of the ASICs. The wafer-level silicon photonic layer 424 can also include a stackable oxide layer (and/or stackable dielectric layer when present) at the stackable-interface surface 430. The stackable oxide layer can bond with respective oxide layers of the ASICs. In other implementations, the ASICs can be attached to the wafer-level silicon photonic layer 424 using a copper pillar flip chip process, a microbump flip chip technique, or a thermocompression bonding process. In some implementations, some combination of these techniques can be used, including hybrid bonding in combination with one or more of the other noted techniques. The ASICs can be electrically coupled with their associated EICs 432, e.g., by way of electrical wiring extending through the silicon photonic layer, the glass substrate, or both. Such electrical wiring can be arranged in the wafer-level silicon photonic layer 424, the wafer-level glass substrate 422, or both, e.g., prior to attachment of the EICs 432, the attachment of the ASICs, or prior to both.

Further, in some implementations, particularly when optical engines are to be formed from the bonded PIC wafer 420 and the glass substrate wafer 422 (e.g., by dicing the assembly during a singulation process at 414 and attaching FAUs 444 at 416), the glass substrate wafer 422 can include a plurality of metallization sets, with each metallization set including TGVs, redistribution layers, and metal contacts organized in a manner to correspond to predefined mounting locations of the components to be stacked directly or indirectly thereon, such as EICs, ASICs, light sources, etc. The strategic arrangement of the metallization sets (rather than having TGVs, redistribution layers, and metal contacts arranged across the entire glass substrate wafer 422) can reduce material and labor costs and can reduce processing time. In some implementations, the metallization sets can be arranged as repeating sets that can abut or be spaced from one another.

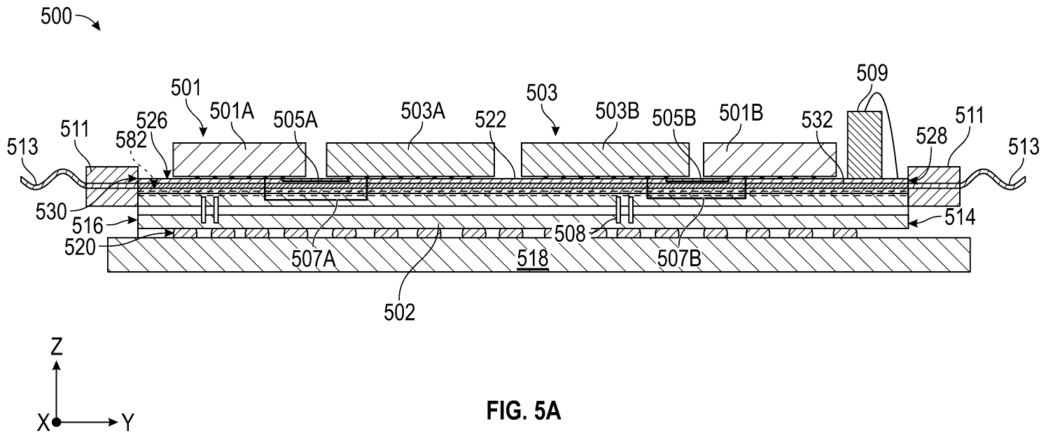

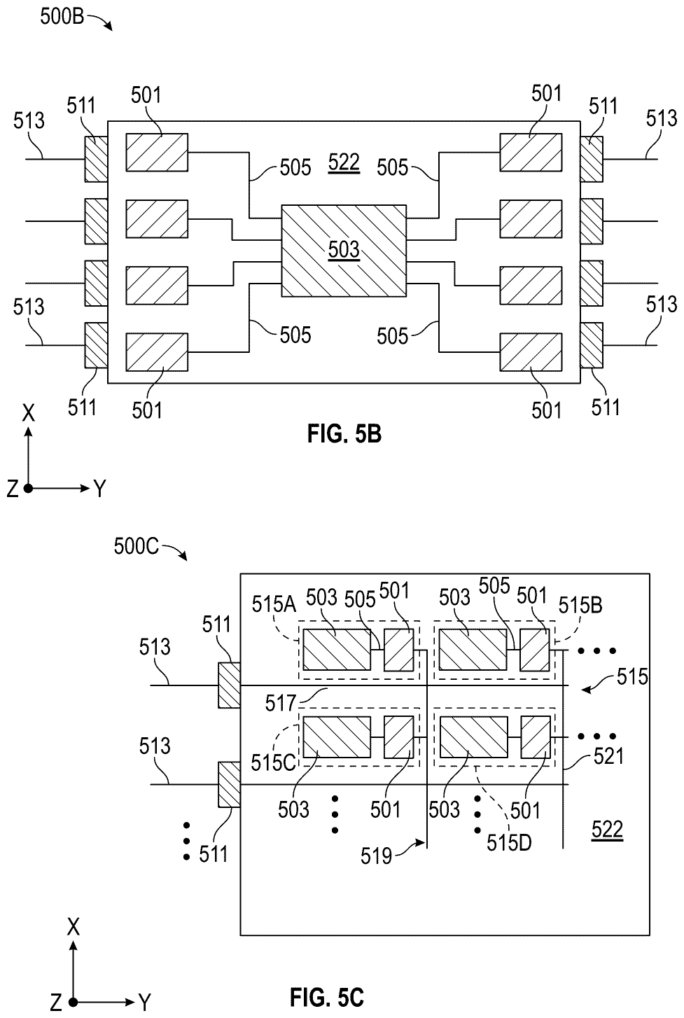

FIG. 5A is a schematic side view of a device 500 according to another example embodiment of the present disclosure. The device 500 of FIG. 5A is constructed in a similar manner as the device 100 of FIG. 1A (and the device 300 of FIG. 3). Accordingly, similar numerals will be utilized to refer to like structures, except that 500 series numbers will be utilized to describe the device 500 of FIG. 5A.

As shown in FIG. 5A, the device 500 is arranged as a hybrid silicon photonic-on-glass optically interconnected Multi-Chip-Module (MCM). The device 500 includes a glass substrate 502 arranged on a PCB 518, e.g., by way of BGAs 520. The glass substrate 502 has TGVs 508 spanning along the third direction Z, e.g., between top and bottom RDLs. A silicon photonic layer 522 is stacked on the glass substrate 502 and is bonded thereto by a hybrid bond 582, e.g., by way of a metal-to-metal, oxide-to-oxide hybrid bond.

The device 500 includes EICs 501 and ASICs 503 coupled with the silicon photonic layer 522. In this regard, multiple optical engines and ASICs 503 can be integrated onto a large body hybrid silicon photonic-on-glass substrate. The EICs 501 can be flipchip bonded to the silicon photonic layer 522. Stackable metal vias revealed or exposed when a silicon handle is removed from the silicon photonic layer 522 during assembly can provide electrical connection points to which solder bumps can be applied to attach the EICs 501 with a stackable-interface surface 526 of the silicon photonic layer 522. In addition, the ASICs 503 can be stacked on the silicon photonic layer 522 and arranged side-by-side or juxtaposed relative to the EICs 501. The ASICs 503 can be ASICs, such as NPUs, GPUs, CPUs, FPGAs, some combination thereof, etc. The ASICs 503 can be flipped and bonded to the silicon photonic layer 522, e.g., by way of solder bumps. In some alternative embodiments, the EICs 501 and/or the ASICs 503 can be hybrid bonded to the silicon photonic layer 522, e.g., by way of a metal-to-metal, oxide-to-oxide hybrid bond. For instance, when the silicon handle is removed during assembly, stackable metal vias and a stackable oxide layer (and/or stackable dielectric layer, when present) can be revealed and used to hybrid bond the EICs 501 and/or ASICs 503 thereto.

A first EIC 501A can be electrically coupled with a first ASIC 503A while a second EIC 501B can be electrically coupled with a second ASIC 503B. For instance, high density local electrical wiring can be used to electrically couple the EICs 501 with the ASICs 503. In FIG. 5A, a first electrical wire 505A provides a first electrical path between the first EIC 501A and the first ASIC 503A while a second electrical wire 507A provides a second electrical path between the first EIC 501A and the first ASIC 503A. The first electrical wire 505A traverses through the silicon photonic layer 522 while the second electrical wire 507A traverses through the silicon photonic layer 522 and the glass substrate 502. Similarly, a first electrical wire 505B provides a first electrical path between the second EIC 501B and the second ASIC 503B while a second electrical wire 507B provides a second electrical path between the second EIC 501B and the second ASIC 503B. The first electrical wire 505B traverses through the silicon photonic layer 522 while the second electrical wire 507B traverses through the silicon photonic layer 522 and the glass substrate 502.

A light source 509 can be stacked on the silicon photonic layer 522, or rather, coupled with the stackable-interface surface 526 thereof as illustrated in FIG. 5A. The light source 509, e.g., a Laser MicroPackage (LaMP), can be attached to the silicon photonic layer 522 to inject optical power into the device 500. Similarly, an optical gain material (e.g., SOA) can be bonded onto the silicon photonic layer 522 and integrated with the waveguide network and photonic devices thereof.

The silicon photonic layer 322 also has a prong coupler 532 that optically couples one or more FAUs 511 with waveguides of the silicon photonic layer 522. The FAUs 511 can include one or more optical fibers 513 (e.g., single mode optical fibers) optically coupled with the prong coupler 532 as shown in FIG. 5A. In at least some embodiments, an index matching epoxy can couple one or more of the FAUs 511 with the silicon photonic layer 522 and the glass substrate 502.

For the depicted embodiment of FIG. 5A, the silicon photonic layer 522 has a first side edge 528, which provides an optical facet or optical coupling interface between one of the FAUs 511 and the silicon photonic layer 522. The first side edge 528 can be substantially coplanar with a first side edge 514 of the glass substrate 502. That is, the first side edge 528 of the silicon photonic layer 522 can be arranged in a same or substantially a same plane as the first side edge 514 of the glass substrate 502, wherein the plane is orthogonal to the second direction Y. The silicon photonic layer 522 and the glass substrate 502 can be diced, with the silicon photonic layer 522 arranged on the glass substrate 502, so that the first side edge 528 of the silicon photonic layer 522 and the first side edge 514 of the glass substrate 502 are formed concurrently or in a single dice movement (e.g., in a single laser pass), rendering diced coplanar edges. The silicon photonic layer 522 also has a second side edge 530, which provides an optical facet or optical coupling interface between one of the FAUs 511 and the silicon photonic layer 522. The second side edge 530 can be substantially coplanar with a second side edge 516 of the glass substrate 502. That is, the second side edge 530 of the silicon photonic layer 522 can be arranged in a same or substantially a same plane as the second side edge 516 of the glass substrate 502, wherein the plane is orthogonal to the second direction Y. The silicon photonic layer 522 and the glass substrate 502 can be diced, with the silicon photonic layer 522 arranged on the glass substrate 502, so that the second side edge 530 of the silicon photonic layer 522 and the second side edge 516 of the glass substrate 502 are formed concurrently or in a single dice movement (e.g., in a single laser pass), rendering diced coplanar edges. While the FAUs 511 are shown as edge-coupled FAUs in FIG. 5A, in alternative embodiments, one or more of the FAU 511 can be surface-coupled FAUs, or rather, attached to the stackable-interface surface 526 of the silicon photonic layer 522.

The device 500 can be assembled at the wafer level, which can provide enhanced manufacturing quality and yield. The device 500 of FIG. 5A can be assembled in a similar manner as the method 400 of FIG. 4A, for example. The device 500 of FIG. 5A can be implemented as part of a CPO package with one or more ASICs communicating externally with optical interconnects or as a large computational array including multiple ASICs (e.g., GPUs/TPUs/NPUs), and memory stacks interconnected via photonic waveguides and coupled to the external world by way of one or more FAUs.

As a first example implementation of the device 500 of FIG. 5A, FIG. 5B is a schematic top view of one example device 500B arranged as a CPO system enabled by a hybrid silicon photonic-on-glass substrate. The device 500B includes the silicon photonic layer 522 hybrid bonded to the glass substrate (the glass substrate is not shown in FIG. 5B but is arranged below the silicon photonic layer 522). The silicon photonic layer 522 can be bonded to the glass substrate by way of a metal-to-metal, oxide-to-oxide hybrid bond, for example. The glass substrate can include metallization sets, with each metallization set including TGVs, redistribution layers, and metal contacts organized in a manner to correspond to predefined mounting locations of the EICs 501 and the ASIC 503 (e.g., a switch ASIC). The silicon photonic layer 522, and in some embodiments the glass substrate, can include electrical wires 505 that couple the EICs 501 with the ASIC 503. Stated differently, the silicon photonic layer 522 and the glass substrate can enable fine pitch wiring between a host ASIC 503 and EICs 501. The fibers 513 supported by the respective FAUs 511 can optically couple with the optical elements of the silicon photonic layer 522. The device 500B can be assembled, e.g., in a similar manner as the method 400 of FIG. 4A, for example. The intimate integration of the silicon photonics layer 522 with the glass substrate can help shrink the overall footprint of the device 500B, namely because TSVs and C4/bump interconnects are not needed or there is a reduced need therefore, being replaced with tighter pitch hybrid bumps.

As a second example implementation of the device 500 of FIG. 5A, FIG. 5C is a schematic top view of one example device 500C arranged as an optically-interconnected computational system enabled by a hybrid silicon photonic-on-glass substrate. The device 500C includes the silicon photonic layer 522 hybrid bonded to the glass substrate (the glass substrate is not shown in FIG. 5C but is arranged below the silicon photonic layer 522). The silicon photonic layer 522 can be bonded to the glass substrate by way of a metal-to-metal, oxide-to-oxide hybrid bond, for example. The glass substrate can include metallization sets, with each metallization set including TGVs, redistribution layers, and metal contacts organized in a manner to correspond to predefined mounting locations of the EICs 501 and the ASICs 503. The ASICs 503 can be compute elements, such as GPUs, NPUs, Tensor Processing Units (TPU), etc.). The device 5000 can also include one or more memory elements, e.g., High Bandwidth Memory (HBM) or other suitable memory devices.

The device 5000 can include a plurality of nodes 515, with each node including at least one of the EICs 501 and at least one of the ASICs 503 or memory devices. While the device 5000 of FIG. 5C includes four (4) nodes, the device 5000 can include more or less than four (4) nodes in other example embodiments. The nodes 515 include a first node 515A, a second node 515B, a third node 515C, and a fourth node 515D. The EIC 501 and the ASIC 503 of a given node can be coupled by way of an electrical wire 505 arranged, at least in part, in the silicon photonic layer 522. The electrical wires 505 can also traverse, at least in part, through the glass substrate hybrid bonded to the silicon photonic layer 522. Further, the silicon photonic layer 522 can include electrical interconnects 517 (e.g., high density electrical interconnects) that provide for “near” node communication, or rather, communication between ASICs 503 of neighboring nodes 515. In FIG. 5C, the ASIC 503 of the first node 515A is coupled with the ASIC 503 of the third node 515C by way of the electrical interconnects 517. In addition, the silicon photonic layer 522 can include a waveguide routing network 519 formed by a plurality of interconnected waveguides 521. The waveguide routing network 519 can be a single mode waveguide network that enables low-latency optical communication between nodes 515 of the device 500C. For example, a point-to-point network or other optimal configuration may be used. Also, the edge-coupled FAUs 511 and their associated fibers 513 can provide off-package optical communication and may be used to bring in optical power to the device 5000.

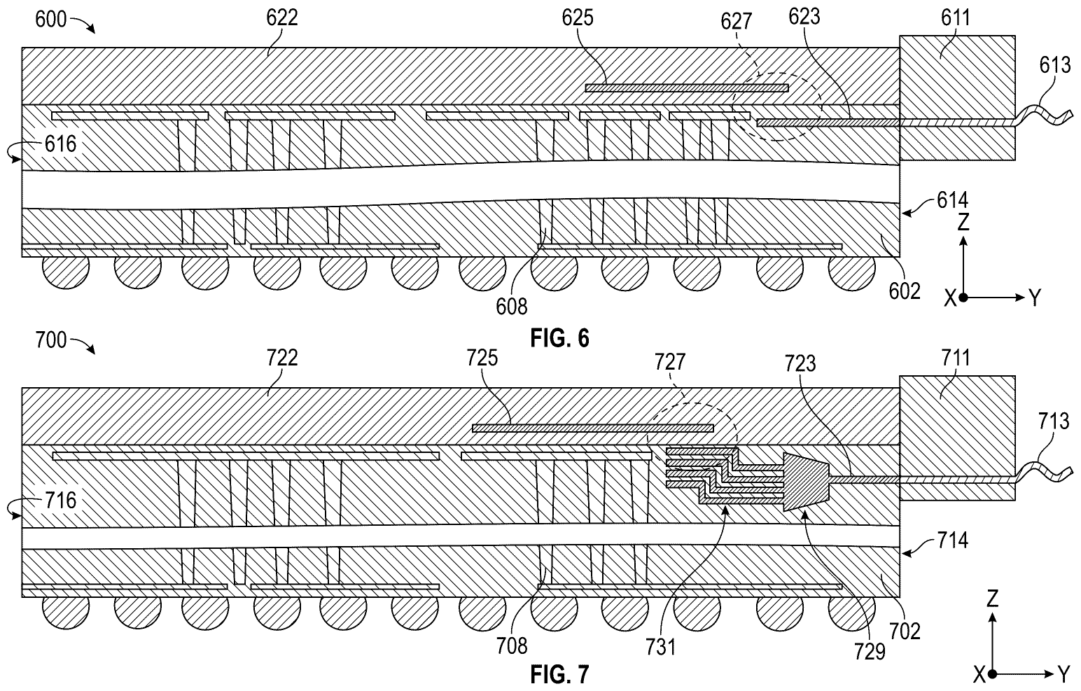

FIG. 6 is a schematic side view of a device 600 according to yet another example embodiment of the present disclosure. The device 600 of FIG. 6 is constructed in a similar manner as the device 100 of FIG. 1A. Accordingly, similar numerals will be utilized to refer to like structures, except that 600 series numbers will be utilized to describe the device 600 of FIG. 6.

As shown in FIG. 6, the device 600 includes a glass substrate 602 having TGVs 608. The glass substrate 602 also includes one or more waveguides 623 (only one shown in FIG. 6). The waveguide 623 can be written to the glass substrate 602 and can be a single mode optical waveguide, for example. The waveguide 623 can be coupled with the optical fiber 613, which is supported by the FAU 611, at the first side edge 614 of the glass substrate 602 and can extend toward a second side edge 616 of the glass substrate 602 along the second direction Y. A silicon photonic layer 622 is hybrid bonded to the glass substrate 602, e.g., by way of a metal-to-metal, oxide-to-oxide hybrid bond. The silicon photonic layer 622 includes a waveguide 625 that overlaps the waveguide 623 of the glass substrate 602 along the second direction Y but is spaced from the waveguide 623 along the third direction Z. The waveguide 623 can be optically coupled with the waveguide 625 by way of an evanescent coupling 627. Stated differently, the layer-to-layer optical coupling can be achieved by evanescent optical coupling between the nitride waveguides 625 of the silicon photonic layer 622 and the waveguides 623 of the glass substrate 602. Accordingly, the device 600 of FIG. 6 has a multilayer single-mode optical routing network, which in this example embodiment is a 2-layer single-mode optical routing network. Multilayer optical routing can advantageously reduce the footprint of a CPO or optical MCM system. The arrangement of the optical elements of the silicon photonic layer 622 and the optical elements of the glass substrate 602 can minimize layer-to-layer coupling losses. Alignment of the waveguides 623, 625 can advantageously be facilitated by the wafer-to-wafer bonding process described herein, which can achieve less than 0.5 microns in alignment accuracy.

FIG. 7 is a schematic side view of a device 700 according to yet another example embodiment of the present disclosure. The device 700 of FIG. 7 is constructed in a similar manner as the device 100 of FIG. 1A. Accordingly, similar numerals will be utilized to refer to like structures, except that 700 series numbers will be utilized to describe the device 700 of FIG. 7.

As shown in FIG. 7, the device 700 includes a glass substrate 702 having TGVs 708. The glass substrate 702 also includes one or more waveguides 723 (only one shown in FIG. 7). The waveguide 723 can be written to the glass substrate 702 and can be a single mode optical waveguide, for example. The waveguide 723 can be coupled with the optical fiber 713, which is supported by the FAU 711, at a first side edge 714 of the glass substrate 702 and can extend toward a second side edge 716 of the glass substrate 702 along the second direction Y.

The device 700 can also include passive optical devices written in the glass substrate 702. For example, the glass substrate 702 can include (1) demultiplexers; (2) a mode expander to improve coupling into an edge-coupled FAU, and/or (3) high reflectance mirrors under silicon photonic grating couplers to increase surface normal output coupling. In FIG. 7, the device 700 includes a multiplexing device 729, which can function as a multiplexer, demultiplexer, or both. Accordingly, multiplexing and/or demultiplexing functionality can be offloaded to and incorporated in the glass substrate 702. The multiplexing device 729 is optically coupled with the waveguide 723 at one end and with a plurality of waveguides 731 at the other end. Generally, a multiplexer can be used to combine optical signals of various wavelengths into a single composite signal in a transmit direction while a demultiplexer can be used to separate a composite optical signal into individual wavelengths.

A silicon photonic layer 722 is hybrid bonded to the glass substrate 702, e.g., by way of a metal-to-metal, oxide-to-oxide hybrid bond. The silicon photonic layer 722 includes a waveguide 725 that overlaps the waveguides 731 of the glass substrate 702 along the second direction Y but is spaced from the waveguides 731 along the third direction Z. The waveguides 731 can be optically coupled with the waveguide 725 by way of an evanescent coupling 727. Stated differently, the layer-to-layer optical coupling can be achieved by evanescent optical coupling between the nitride waveguides 725 of the silicon photonic layer 722 and the waveguides 731 of the glass substrate 702. Accordingly, the device 700 of FIG. 7 has a multilayer single-mode optical routing network, which in this example embodiment is a 2-layer single-mode optical routing network. Multilayer optical routing can advantageously reduce the footprint of a CPO or optical MCM system. The arrangement of the optical elements of the silicon photonic layer 722 and the optical elements of the glass substrate 702 can minimize layer-to-layer coupling losses. Alignment of the waveguides 725, 731 can advantageously be facilitated by the wafer-to-wafer bonding process described herein, which can achieve less than 0.5 microns in alignment accuracy.

In the current disclosure, reference is made to various embodiments. However, the scope of the present disclosure is not limited to specific described embodiments. Instead, any combination of the described features and elements, whether related to different embodiments or not, is contemplated to implement and practice contemplated embodiments. Additionally, when elements of the embodiments are described in the form of “at least one of A and B,” or “at least one of A or B,” it will be understood that embodiments including element A exclusively, including element B exclusively, and including element A and B are each contemplated. Furthermore, although some embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s).

In view of the foregoing, the scope of the present disclosure is determined by the claims that follow.

We claim:

1. A device, comprising:
a glass substrate having a plurality of through-glass vias (TGVs), an oxide layer, and metal contacts coupled with the TGVs; and
a silicon photonic layer having metal pads and an oxide layer, the metal pads are bonded with the metal contacts and the oxide layer of the silicon photonic layer is bonded with the oxide layer of the glass substrate such that the silicon photonic layer is hybrid bonded to the glass substrate by a metal-to-metal, oxide-to-oxide hybrid bond.

2. The device of claim 1, wherein the silicon photonic layer has a substrate-interface surface arranged in contact with the glass substrate, and wherein at least one of the metal pads is connected to a hub layer of the silicon photonic layer by a metal via, the at least one metal pad is arranged flush with the substrate-interface surface and bonded with one of the metal contacts of the glass substrate.

3. The device of claim 2, wherein the silicon photonic layer has a buried insulation layer and an optical detector arranged on one side of the buried insulation layer, and wherein the at least one metal pad that is arranged flush with the substrate-interface surface is arranged on a side of the buried insulation layer opposite the optical detector.

4. The device of claim 1, wherein the silicon photonic layer has a substrate-interface surface and a stackable-interface surface defining a thickness of the silicon photonic layer, and wherein the silicon photonic layer has a stackable metal via arranged flush with the stackable-interface surface.

5. The device of claim 1, further comprising:
an electrical integrated circuit (EIC) bonded to a stackable-interface surface of the silicon photonic layer;
a light source bonded to the stackable-interface surface; and
an application-specific integrated circuit (ASIC) bonded to the stackable-interface surface, the ASIC being electrically coupled with the EIC by one or more electrical wires extending, at least in part, through the silicon photonic layer.

6. The device of claim 1, wherein a thickness ratio is defined as a thickness of the glass substrate to a thickness of the silicon photonic layer, and wherein the thickness ratio is between 5:1 and 40:1.

7. The device of claim 1, wherein the silicon photonic layer has a waveguide embedded therein and the glass substrate has a waveguide embedded therein, and wherein the waveguide of the silicon photonic layer is coupled with the waveguide of the glass substrate by an evanescent optical coupling.

8. The device of claim 1, wherein the silicon photonic layer has a waveguide embedded therein, and the glass substrate has one or more waveguides and a passive optical device embedded therein, and wherein the waveguide of the silicon photonic layer is coupled with the one or more waveguides of the glass substrate by an evanescent optical coupling.

9. A device, comprising:
a glass substrate having a plurality of through-glass vias (TGVs), a plurality of metal contacts coupled with the TGVs, and an oxide layer;
a silicon photonic layer having a substrate-interface surface and a stackable-interface surface defining a thickness of the silicon photonic layer, the silicon photonic layer having a plurality of metal pads and an oxide layer arranged along the substrate-interface surface and a plurality of stackable metal vias arranged at the stackable-interface surface, wherein the plurality of metal pads are bonded with respective ones of the plurality of metal contacts and the oxide layer of the glass substrate is bonded with the oxide layer of the silicon photonic layer to form a hybrid bond between the glass substrate and the silicon photonic layer; and
an electronic integrated circuit (EIC) stacked on the silicon photonic layer and coupled with the plurality of stackable metal vias.

10. The device of claim 9, comprising:
an integrated circuit stacked on the silicon photonic layer and coupled with the EIC by way of one or more electrical wires extending through the silicon photonic layer and the glass substrate.

11. The device of claim 9, wherein the EIC is one of a plurality of EICs of the device, and wherein each one of the plurality of EICs is coupled with an application-specific integrated circuit (ASIC), wherein each one of the plurality of EICs and the ASIC are bonded to the stackable-interface surface of the silicon photonic layer.

12. The device of claim 9, wherein the EIC is one of a plurality of EICs of the device and the device includes a plurality of application-specific integrated circuits (ASICs), and wherein the device has a plurality of nodes, with each one of the plurality of nodes including one of the plurality of EICs and one of the plurality of ASICs, and wherein the EIC and the ASIC of each one of the plurality of nodes are electrically coupled with one another and bonded to a stackable-interface surface of the silicon photonic layer.

13. The device of claim 12, wherein the silicon photonic layer includes a waveguide network optically interconnecting the plurality of EICs of the plurality of the nodes.

14. The device of claim 12, wherein an ASIC of the plurality of ASICs from one of the plurality of nodes is directly electrically coupled with an ASIC of the plurality of ASICs from another one of the plurality of nodes by way of one or more electrical interconnects.

15. A method, comprising:
hybrid bonding a PIC wafer to a glass substrate wafer having through-glass vias (TGVs), the PIC wafer having a wafer-level silicon photonic layer and a wafer-level silicon handle;
removing the wafer-level silicon handle of the PIC wafer while the wafer-level silicon photonic layer remains hybrid bonded to the glass substrate wafer;
attaching a plurality of integrated circuits to the wafer-level silicon photonic layer; and
performing wafer singulation to create respective electro-optical packages, with each electro-optical package including a silicon photonic layer separated from the wafer-level silicon photonic layer, at least one of the plurality of integrated circuits, and a glass substrate separated from the glass substrate wafer, the glass substrate having at least one of the TGVs,
wherein in performing the wafer singulation, at least one electro-optical package of the electro-optical packages is diced so that an optical interface of the silicon photonic layer is created by the dicing.

16. The method of claim 15, wherein the PIC wafer is hybrid bonded to the glass substrate wafer in a facedown orientation so that the wafer-level silicon photonic layer is arranged face-to-face with the glass substrate wafer.

17. The method of claim 15, further comprising:
after removing the wafer-level silicon handle, performing a backend process on the wafer-level silicon photonic layer.

18. The method of claim 15, further comprising:
performing, prior to wafer singulation, a wafer level test using a test card to test which ones of the electro-optical packages satisfy an operational threshold.

19. The method of claim 15, further comprising:
coupling a fiber array unit to the optical interface of the silicon photonic layer.

20. The method of claim 15, wherein, after removing the wafer-level silicon handle, one or more stackable metal vias are revealed at a stackable-interface surface of the wafer-level silicon photonic layer.
